(19) United States
(12) Patent Application Publication
(10) Pub. No.: US 2015/0338448 A1
(43) Pub. Date: Nov. 26, 2015

(54) NOISE DETECTION DEVICE, SYSTEM AND METHOD

(71) Applicant: Novatek Microelectronics Corp., Hsinchu (TW)

(72) Inventors: Hung-Cheng Kuo, Hsinchu City (TW); Po-Wei Chen, Hsinchu County (TW); Chun-Hung Chen, Taipei City (TW)

(73) Assignee: Novatek Microelectronics Corp., Hsinchu (TW)

(21) Appl. No.: 14/285,604

(22) Filed: May 22, 2014

(51) Int. Cl. G01R 29/26

(52) U.S. Cl. CPC G01R 29/26

(57) ABSTRACT

A noise detection device, system, and a method of detecting noise signals are disclosed. The noise detection device includes a drive circuit, a sense circuit and a controller. The drive circuit drives a plurality of drive lines having a first polarity pattern and a second polarity pattern, wherein an operation of the first polarity pattern and the second polarity pattern substantially equals zero over a predetermined time period. The sense circuit senses a plurality of sense signals from at least one sense line during the predetermined time period. The controller derives a magnitude of a noise signal from the at least one sense line according to the sense signals.

### BACKGROUND

1. Technical Field

The invention relates generally to a device, system, and method of detecting noise signals. More particularly, the invention relates to a noise detection device, system, and method that measures noise signals by adopting drive signals having patterns that substantially equal to zero over a predetermined amount of time.

2. Related Art

With the rapid advancement of information technology, wireless mobile communication, and information electric appliances in the recent years, the input devices for a great many information electronic products have changed from conventional keyboards and mice to touch panels due to convenience, miniaturization, and user-friendliness. In particular, a touch sensing display device has become the most popular product among all.

Noise detection in electronic communication products with touch sensing display devices is typically achieved by two types of mechanisms. In the first method, noise analysis of the transmission channels is performed before signals are transmitted through the channels. This method costs extra time, lowers the signal transmission rate, and reduces the data report rate in the touch systems. In the second method, noise analysis is done after data is received to determine whether the data is noisy. This method requires noise analysis circuitry that is sufficiently fast to match the data transmission rate, so as to prevent a decrease in the report rate. Moreover, to ensure a preferably low false report rate, this type of noise analysis method needs to be accurate without adding circuit complexity or lowering the report rate.

### SUMMARY

Several exemplary embodiments accompanied with figures are described in detail below to further describe the invention in details.

The invention provides a noise detection system and a noise detection device. The noise detection system includes a touch panel and a noise detection device. The touch panel includes a plurality of drive lines and a plurality of sense lines. The noise detection device includes a drive circuit, a sense circuit, and a controller. The drive circuit drives the plurality of drive lines with drive signals having a first polarity pattern and a second polarity pattern, in which an operation of the first polarity pattern and the second polarity pattern substantially equals zero over a predetermined time period. The sense circuit senses a plurality of sense signals from at least one sense line during the predetermined time period. The controller derives a magnitude of a noise signal from the at least one sense line according to the sense signals.

According to an embodiment of the invention, the drive circuit drives the drive lines with drive signals having the first polarity pattern and the second polarity pattern, in which the operation of the first polarity pattern and the second polarity pattern substantially equals zero over the predetermined time period, by applying a first group of drive signals having the first polarity pattern in a first portion of the predetermined time period, and applying drive signals having the second polarity pattern in a second portion of the predetermined time period.

According to an embodiment of the invention, the first polarity pattern and the second polarity pattern sum to zero, and the first portion and the second portion of the predetermined time period are consecutive time slots in the predeteimined time period.

According to an embodiment of the invention, the first polarity pattern and the second polarity pattern sum to zero, and the first portion and the second portion of the predetermined time period are consecutive groups of time slots in the predetermined time period.

According to an embodiment of the invention, the first polarity pattern subtracted by the second polarity pattern equals to zero, and the first portion and the second portion of the predetermined time period are consecutive groups of time slots in the predetermined time period.

According to an embodiment of the invention, the noise detection device further includes a plurality of analog-to-digital converters coupled between the sense lines and the sense circuit. The analog-to-digital converters integrate the sense signals over time in order to convert the analog sense signals to digital sense signals.

According to an embodiment of the invention, the controller derives the magnitude of the noise signal according to the sense signals by summing the sense signals.

From another perspective, the invention provides a method for detecting noise signals, including the following steps. A plurality of drive lines are driven with drive signals having a first polarity pattern and a second polarity pattern, in which an operation of the first polarity pattern and the second polarity pattern substantially equals zero over a predetermined time period. A plurality of sense signals are sensed from at least one sense line during the predetermined time period. A magnitude of a noise signal from the at least one sense line is derived according to the sense signals.

According to an embodiment of the invention, the step of driving the plurality of drive lines with drive signals having the first polarity pattern and the second polarity pattern, in which the operation of the first polarity pattern and the second polarity pattern substantially equals zero over the predetermined time period includes, applying a first group of drive signals having the first polarity pattern in a first portion of the predetermined time period, and applying drive signals having the second polarity pattern in a second portion of the predetermined time period.

According to an embodiment of the invention, the first polarity pattern and the second polarity pattern sum to zero, and the first portion and the second portion of the predetermined time period are consecutive time slots in the predetermined time period.

According to an embodiment of the invention, the first polarity pattern and the second polarity pattern sum to zero, and the first portion and the second portion of the predetermined time period are consecutive groups of time slots in the predetermined time period.

According to an embodiment of the invention, the first polarity pattern subtracted by the second polarity pattern equals to zero, and the first portion and the second portion of the predetermined time period are consecutive groups of time slots in the predetermined time period.

According to an embodiment of the invention, the step of sensing the sense signals from the at least one sense line during the predetermined time period includes integrating the sense signals over time in order to convert the sense signals to digital sense signals.

According to an embodiment of the invention, the step of deriving the magnitude of the noise signal according to the sense signals includes summing the sensed signals.

In summary, by driving a plurality of drive lines with drive signals equaling zero over a predetermined time period, additive noise such as LCM noise and charger noise can be rapidly analyzed without adding circuit complexity. Accordingly, the report rate of the touch system can be increased while the noise condition of the touch system can be fully profiled.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the invention.

FIG. 1 is a schematic view of a noise detection system according to an embodiment of the invention.

FIG. 2 is a partial schematic view of the touch panel in the noise detection system of FIG. 1 according to an embodiment of the invention.

FIG. 3 is a schematic diagram illustrating the data obtained from the touch panel in the noise detection system of FIG. 1 according to an embodiment of the invention.

FIG. 4 is a flow diagram of a method for detecting noise signals according to an embodiment of the invention.

### DETAILED DESCRIPTION OF DISCLOSED EMBODIMENTS

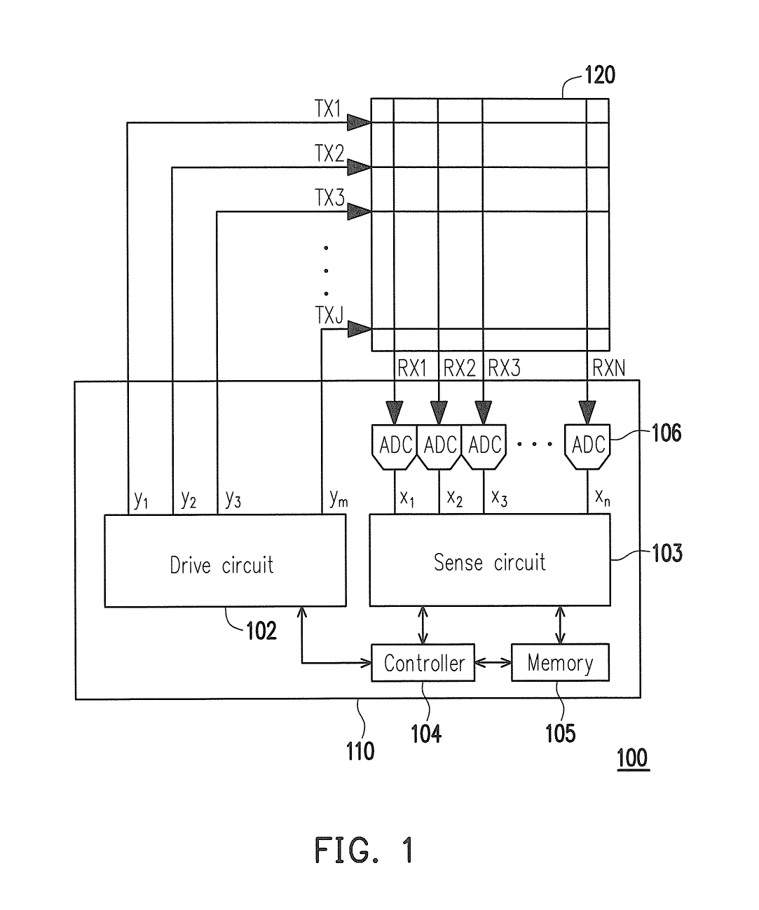

FIG. 1 is a schematic view of a noise detection system according to an embodiment of the invention. With reference to FIG. 1, a noise detection system 100 includes a noise detection device 110 and a touch panel 120. In the present embodiment, the touch panel 120 includes a plurality of drive lines TX1, TX2, TXJ and a plurality sense lines RX1, RX2, RXN. The noise detection device 110 includes a drive circuit 102, a sense circuit 103, a controller 104, a memory 105, and a plurality of analog-to-digital converters (ADCs) 106. The drive circuit 102 may drive the drive lines RX1-RXN with drive signals y₁, y₂, . . . , yₘ having a first polarity pattern and a second polarity pattern, in which an operation of the first polarity pattern and the second polarity pattern substantially equals zero over a predetermined time period. Details of how the drive lines TX1-TXJ are driven with the drive signals y₁-yₘ are shown later in the disclosure. The sense circuit 103 may sense a plurality of sense signals from at least one of the sense lines RX1-RXN during the predetermined time period. The ADCs 106 may be coupled between the sense lines RX1-RXN and the sense circuit 103. Moreover, the ADCs may integrate the sense signals from the sense lines RX1-RXN over time in order to convert the analog sense signals to a plurality of digital sense signals x₁, x₂, . . . , xₙ. The digital sense signals x₁-xₙ may be stored in the memory 105 with digital data format, which is coupled to the sense circuit 103 and the controller 104, or the digital sense signals x₁-xₙ may be directly transmitted to the controller 104 for processing. The controller 104 may derive a magnitude of a noise signal from the at least one sense lines RX1-RXN according to the digital sense signals x₁-xₙ, such as by summing the digital sense signals x₁-xₙ using a digital signal processor (not shown) in the controller 104, although the invention is not limited thereto. Details of the mechanisms in which the controller 104 derives the magnitude of the nosise signals from the sense lines RX1-RXN will be further described later in the disclosure.

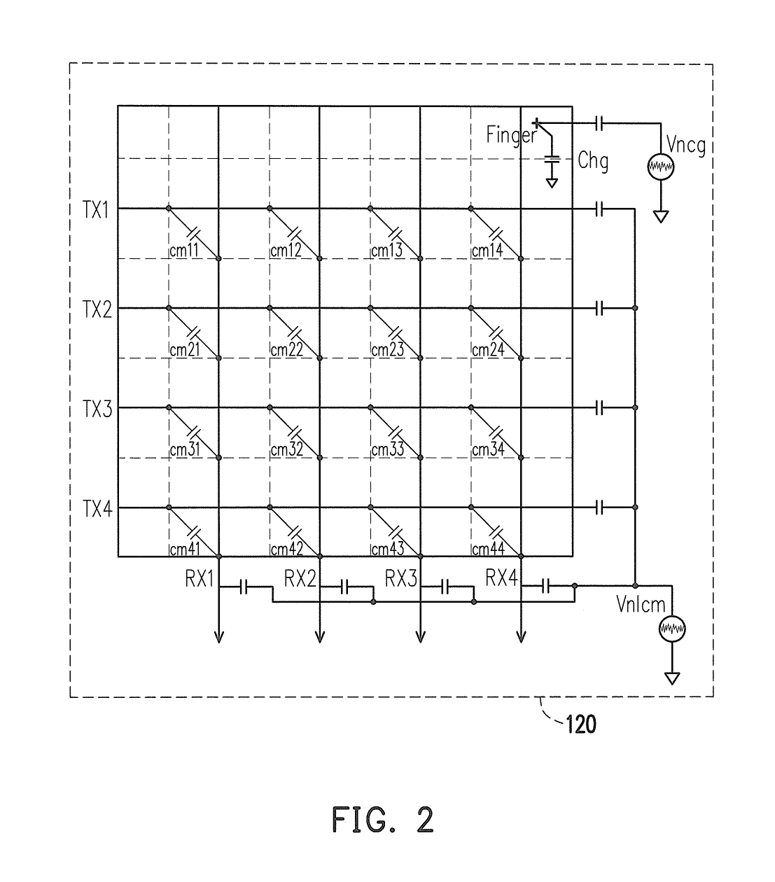

FIG. 2 is a partial schematic view of the touch panel in the noise detection system of FIG. 1 according to an embodiment of the invention. With reference to FIG. 2, four drive lines TX1-TX4 and four sense lines RX1-RX4 are shown as an illustrative example. In the present embodiment, the touch panel 120 may be a capacitive touch panel that determines the touch information of the touch panel 120 using a mutual capacitance principle, for example. In the touch panel 120 shown in FIG. 2, signal values on the drive lines TX1-TX4 sensed by sense lines RX1-RX4 may originate from two sources: 1) mutual capacitance between the drive lines TX1-TX4 and sense lines RX1-RX4 and the noise signals thereof, represented by the quantity Cm, and 2) other noise signals not originating from Cm. Typically, signals or noise related to Cm directly correlates with the quantity Cm, and thus Cm may be viewed as a multiplicative quantity. On the other hand, as shown in FIG. 2, noise signals not originating from Cm, such as liquid crystal module (LCM) noise Vncg and charger noise Vnlcm, are additive quantities. In the present embodiment, the LCM noise Vnlcm may be due to the coupling of the touch panel 120 to a liquid crystal module (not shown), and the charger noise Vncg may be due to contact by an object (e.g. a finger) on the touch panel 120 causing a capacitance change Chg. In touch systems, additive noise such as the LCM noise Vnlcm and the charger noise Vncg may result in significant false reporting of touch information. Since the data volume of Cm is typically far greater than the LCM noise Vnlcm and the charger noise Vncg, a fast noise detection mechanism that detects the additive noises Vnlcm and Vncg is needed to fully profile the noise condition of the touch panel 120.

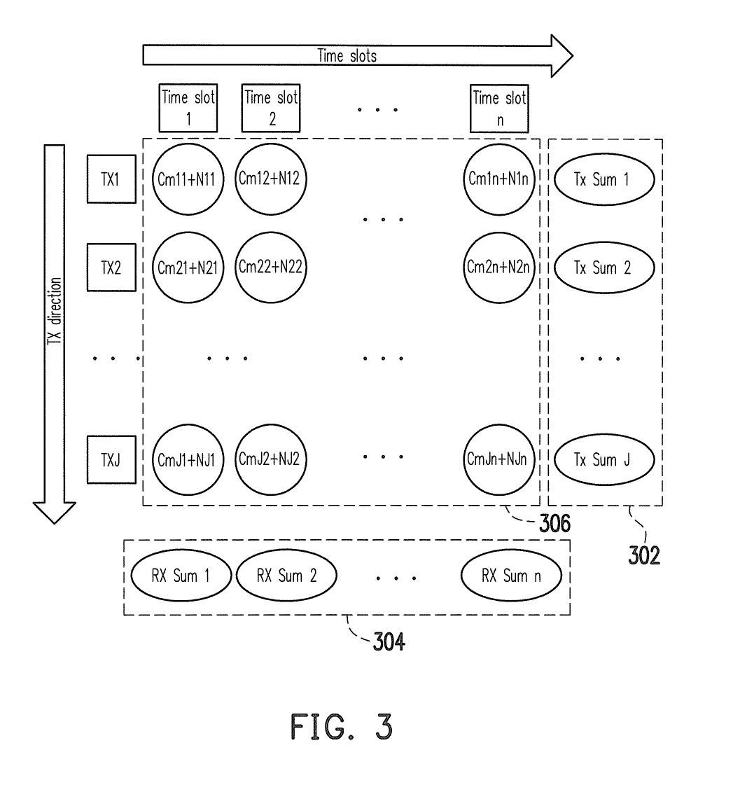

FIG. 3 is a schematic diagram illustrating the data obtained from the touch panel in the noise detection system of FIG. 1 according to an embodiment of the invention. With reference to FIG. 3, the horizontal axis represents time, and the vertical direction represents the drive lines TX1-TXJ. In the present embodiment, time is divided into time slots 1-n, for example. In region 306, the raw data from each intersection of the drive lines TX1-TXJ and the sense lines RX1-RXN is represented by the sum of mutual capacitance Cmji and other additive noise Nji, in which i and j are positive integers greater than or equal to 1. The sense signals from the sense lines RX1-RXN are represented by RX Sumᵢ shown in the region 304 of FIG. 3. In the present embodiment, RX Sumᵢ may be viewed as equal to the data contribution from each of the drive lines TX1-TXJ. For example, RX Sum₁ represents the sum of CM11+N11 to CMJ1+NJ1. The relationship may be described by the following equation:

$$RX {Sum}_{i} = {\sum }_{j = 1}^{J} Cmji + Nji \qquad ( 1 )$$

in which RX Sumᵢ denotes the raw data used by the touch system to determine the touch operation, Cm denotes the data from the mutual capacitance of the drive lines TX1-TXJ and sense lines RX1-RXn, N denotes additive noise data not from Cm, and i and j are positive integers greater than or equal to 1. As shown in FIG. 3, by driving each of the drive lines TX-TXJ with drive signals having a first polarity pattern and a second polarity pattern, in which an operation of the first polarity pattern and the second polarity pattern substantially equals zero over a predetermined time period (e.g. n time slots), the right side of Equation (1) is left with the noise Nji. In other words, additive noise such as the LCM noise Vnlcm and the charger noise Vncg shown in FIG. 2 may be determined by summing RX Sum; shown in region 304 of FIG. 3. Due to the drive lines TX1-TXJ being driven with drive signals equaling zero over time slots n, the sum of the data contribution from the drive lines TX1-TXJ, TX Sumⱼ shown in region 302 would equal to the sum of. That is, the noise detection system 100 of FIG. 1 is able to detect the magnitude of the noise by using simple adder or subtractor circuits (not shown) in the noise detection device 110, for example. As a consequence, the speed of noise analysis is increased without adding circuit complexity.

In order to further illustrate the noise detection methods in the disclosure, several examples of driving schemes driving each of the drive lines TX-TXJ are shown in the description hereafter, with drive signals having a first polarity pattern and a second polarity pattern, in which an operation of the first polarity pattern and the second polarity pattern substantially equals zero over a predetermined time period. It should be noted that alternative driving schemes may be used in other embodiments of the invention. In the examples hereafter, only four drive lines TX0-TX3 are shown, although the driving schemes may be expanded to include more drive lines according to design requirements. It should be further noted that the drive pulses (1 and −1) shown in the tables below represent relative drive pulses of the drive lines TX0-TX3 which are measured relative to a reference point (not shown). In the driving scheme shown in Table 1, the drive pulses of each of the drive lines TX0-TX3 sum to 0 after time slot 1. For the drive line TX0, a negative polarity drive pulse (e.g. −1) is applied in time slot 0, a positive polarity drive pulse (e.g. 1) is applied in time slot 1, and therefore the drive line TX0 is driven with drive signals that equal to zero over two time slots, for example. On the other hand, for the drive line TX1, a positive polarity polarity drive pulse (e.g. 1) is applied in time slot 0, a negative polarity drive pulse (e.g. −1) is applied in time slot 1, and therefore the drive line TX1 is also driven with drive signals that equal to zero over two time slots. The drive schemes of other drive lines in this example may also be similarly interpreted by analogy.

TABLE 1
Drive Scheme Example

| | TX0 | TX1 | TX2 | TX3 |
|---|---|---|---|---|
| Time Slot 0 | −1 | 1 | 1 | −1 |
| Time Slot 1 | 1 | −1 | −1 | 1 |

In the driving scheme shown in Table 2, the driving pulses of each of the drive lines TX0-TX3 sum to 0 after time slot 3. For the drive line TX0, drive pulses of −1 and 1 are applied on time slot 0 and time slot 1, respectively. In time slots 2 and 3, drive pulses of −1 and 1 are applied to the drive line TX0, and therefore the drive line TX0 is driven with drive signals that equal to zero after four time slots (e.g., −1+1−1+1=0). The drive schemes of other drive lines in this example may also be similarly interpreted by analogy.

TABLE 2
Drive Scheme Example

| | TX0 | TX1 | TX2 | TX3 |
|---|---|---|---|---|
| Time Slot 0 | −1 | −1 | 1 | −1 |
| Time Slot 1 | 1 | −1 | −1 | 1 |
| Time Slot 2 | −1 | 1 | −1 | 1 |
| Time Slot 3 | 1 | 1 | 1 | −1 |

In the driving scheme shown in Table 3, each of the drive lines TX0-TX3 may be driven with driving pulses having two different polarity patterns that sum to zero over time slots 0-3. For the drive line TX0, drive pulses having a first polarity pattern (−1, 1, 1, 1) and a second polarity pattern (1, −1, −1, −1) are applied in time slots 0-3, respectively. Accordingly, the drive line TX0 is driven with drive signals that equal to zero after four time slots (−1+1+1+1+1−1−1−1=0). The drive schemes of other drive lines in this example may also be similarly interpreted by analogy.

TABLE 3
Drive Scheme Example

| | TX0 | TX1 | TX2 | TX3 |
|---|---|---|---|---|
| Time Slot 0 | −1 | −1 | 1 | −1 |
| Time Slot 1 | 1 | −1 | −1 | 1 |
| Time Slot 2 | −1 | 1 | −1 | 1 |
| Time Slot 3 | 1 | 1 | 1 | −1 |
| Time Slot 0 | −1 | −1 | 1 | −1 |
| Time Slot 1 | 1 | −1 | −1 | 1 |
| Time Slot 2 | −1 | 1 | −1 | 1 |
| Time Slot 3 | 1 | 1 | 1 | −1 |

In the driving scheme shown in Table 4, each of the drive lines TX0-TX3 may be driven with driving pulses having two different polarity patterns, in which the first polarity pattern subtracted by the second polarity pattern equals to zero over time slots 0-3. For the drive line TX0, drive pulses having a first polarity pattern (−1, 1, 1, 1) and a second polarity pattern (−1, 1, 1, 1) are applied in time slots 0-3, respectively. When the first polarity pattern is subtracted by the second polarity pattern, the difference betweeen the two polarity patterns is zero after time slot 3 (−1+1+1+1−(−1+1+1+1)=0). Accordingly, the drive line TX0 is driven with drive signals that equal to zero after four time slots. The drive schemes of other drive lines in this example may also be similarly interpreted by analogy. Moreover, the drive scheme examples shown in Tables 1-3 may be implemented by a simple adder circuit in the noise detection device 110 of FIG. 1, while the example shown in Table 4 may be implemented by a simple subtractor circuit in the noise detection device 110 of FIG. 1.

TABLE 4
Drive Scheme Example

| | TX0 | TX1 | TX2 | TX3 |
|---|---|---|---|---|
| Time Slot 0 | −1 | −1 | 1 | −1 |
| Time Slot 1 | 1 | −1 | −1 | 1 |
| Time Slot 2 | 1 | 1 | −1 | 1 |
| Time Slot 3 | 1 | 1 | 1 | −1 |
| Time Slot 0 | −1 | −1 | 1 | −1 |
| Time Slot 1 | 1 | −1 | −1 | 1 |
| Time Slot 2 | 1 | 1 | −1 | 1 |
| Time Slot 3 | 1 | 1 | 1 | −1 |

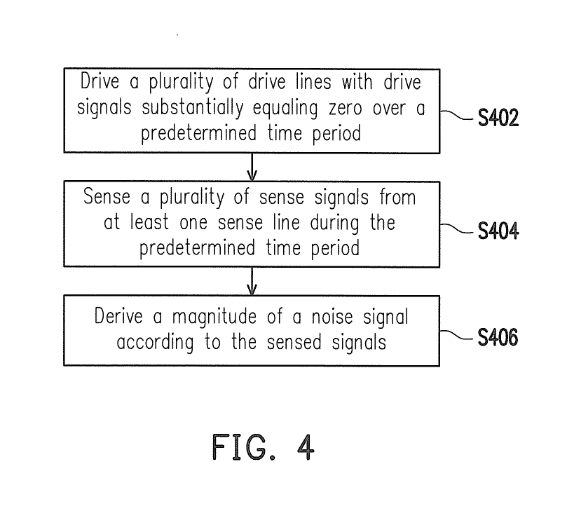

In view of the noise detection system 100 and the noise detection device 110 shown in FIG. 1 and detailed in the foregoing description, a method of detecting noise signals that may also be applied in the noise detection system 100 and the noise detection device 110 may be detailed as follows. FIG. 4 is a flow diagram of a method for detecting noise signals according to an embodiment of the invention. With reference to FIG. 4, in Step S402, a plurality of drive lines are driven with drive signals having a first polarity pattern and a second polarity pattern, in which an operation of the first polarity pattern and the second polarity pattern substantially equals zero over a predetermined time period. Step S404, a plurality of sense signals are sensed from at least one sense line during the predetermined time period. In Step S406, a magnitude of a noise signal from the at least one sense line is derived according to the sense signals. In one embodiment, the step of driving the plurality of drive lines with drive signals having the first polarity pattern and the second polarity pattern, in which the operation of the first polarity pattern and the second polarity pattern substantially equals zero over the predetermined time period includes, applying a first group of drive signals having the first polarity pattern in a first portion of the predetermined time period, and applying drive signals having the second polarity pattern in a second portion of the predetermined time period. In another embodiment, the first polarity pattern and the second polarity pattern sum to zero, and the first portion and the second portion of the predetermined time period are consecutive time slots in the predetermined time period. In another embodiment, the first polarity pattern and the second polarity pattern sum to zero, and the first portion and the second portion of the predetermined time period are consecutive groups of time slots in the predetermined time period. In other embodiments, the first polarity pattern subtracted by the second polarity pattern equals to zero, and the first portion and the second portion of the predetermined time period are consecutive groups of time slots in the predetermined time period. In another embodiment, the step of sensing the sense signals from the at least one sense line during the predetermined time period includes integrating the sense signals over time in order to convert the sense signals to digital sense signals. In other embodiments, the step of deriving the magnitude of the noise signal according to the sense signals includes summing the sensed signals.

In view of the foregoing, by driving a plurality of drive lines with drive signals equaling zero over a predetermined time period, additive noise such as LCM noise and charger noise can be rapidly analyzed without adding circuit complexity. Accordingly, the report rate of the touch system can be increased while the noise condition of the touch system can be fully profiled.

It will be apparent to those skilled in the art that various modifications and variations can be made to the structure of the disclosed embodiments without departing from the scope or spirit of the invention. In view of the foregoing, it is intended that the invention cover modifications and variations of this invention provided they fall within the scope of the following claims and their equivalents.

What is claimed is:

1. A noise detection device, comprising:
a drive circuit driving a plurality of drive lines having a first polarity pattern and a second polarity pattern, wherein an operation of the first polarity pattern and the second polarity pattern substantially equals zero over a predetermined time period;
a sense circuit sensing a plurality of sense signals from at least one sense line during the predetermined time period; and
a controller deriving a magnitude of a noise signal from the at least one sense line according to the sense signals.

2. The noise detection device according to claim 1, wherein the drive circuit drives the drive lines with drive signals having the first polarity pattern and the second polarity pattern, wherein the operation of the first polarity pattern and the second polarity pattern substantially equals zero over the predetermined time period, by applying a first group of drive signals having the first polarity pattern in a first portion of the predetermined time period, and applying drive signals having the second polarity pattern in a second portion of the predetermined time period.

3. The noise detection device according to claim 2, wherein the first polarity pattern and the second polarity pattern sum to zero, and the first portion and the second portion of the predetermined time period are consecutive time slots in the predetermined time period.

4. The noise detection device according to claim 2, wherein the first polarity pattern and the second polarity pattern sum to zero, and the first portion and the second portion of the predetermined time period are consecutive groups of time slots in the predetermined time period.

5. The noise detection device according to claim 2, wherein the first polarity pattern subtracted by the second polarity pattern equals to zero, and the first portion and the second portion of the predetermined time period are consecutive groups of time slots in the predetermined time period.

6. The noise detection device according to claim 1, further comprising:
at least one analog-to-digital converter coupled between the at least one sense line and the sense circuit, the analog-to-digial converter integrating the sense signals over time in order to convert the analog sense signals to digital sense signals.

7. The noise detection device according to claim 1, wherein the controller derives the magnitude of the noise signal according to the sense signals by summing the sense signals.

8. A noise detection system, comprising:
a touch panel comprising a a plurality of drive lines and at least one sense line;
a noise detection device, comprising:
a drive circuit driving a plurality of drive lines with a first polarity pattern and a second polarity pattern, wherein an operation of the first polarity pattern and the second polarity pattern substantially equals zero over a predetermined time period;
a sense circuit sensing a plurality of sense signals from the at least one sense line during the predetermined time period; and
a controller deriving a magnitude of a noise signal from the at least one sense line according to the sense signals.

9. The noise detection device according to claim 8, wherein the drive circuit drives the drive lines with drive signals having the first polarity pattern and the second polarity pattern, wherein the operation of the first polarity pattern and the second polarity pattern substantially equals zero over the predetermined time period, by applying a first group of drive signals having the first polarity pattern in a first portion of the predetermined time period, and applying drive signals having the second polarity pattern in a second portion of the predetermined time period.

10. The noise detection system according to claim 9, wherein the first polarity pattern and the second polarity pattern sum to zero, and the first portion and the second portion of the predetermined time period are consecutive time slots in the predetermined time period.

11. The noise detection system according to claim 9, wherein the first polarity pattern and the second polarity pattern sum to zero, and the first portion and the second portion of the predetermined time period are consecutive groups of time slots in the predetermined time period.

12. The noise detection system according to claim 9, wherein the first polarity pattern subtracted by the second polarity pattern equals to zero, and the first portion and the second portion of the predetermined time period are consecutive groups of time slots in the predetermined time period.

13. The noise detection system according to claim 8, the noise detection device further comprising:
at least one analog-to-digial converter coupled between the at least one sense line and the sense circuit, the at least one analog-to-digial converter integrating the sense signals over time in order to convert the analog sense signals to digital sense signals.

14. The noise detection system according to claim 8, wherein the controller derives the magnitude of the noise signal according to the sense signals by summing the sense signals.

15. A method of detecting noise signals, the method comprising:
driving a plurality of drive lines with drive signals having a first polarity pattern and a second polarity pattern, wherein an operation of the first polarity pattern and the second polarity pattern substantially equals zero over a predetermined time period;
sensing a plurality of sense signals from at least one sense line during the predetermined time period; and
deriving a magnitude of a noise signal from the at least one sense line according to the sense signals.

16. The method of detecting noise signals according to claim 15, wherein the step of driving the plurality of drive lines with drive signals having the first polarity pattern and the second polarity pattern, wherein the operation of the first polarity pattern and the second polarity pattern substantially equals zero over the predetermined time period comprises:
applying a first group of drive signals having the first polarity pattern in a first portion of the predetermined time period; and
applying drive signals having the second polarity pattern in a second portion of the predetermined time period

17. The method of detecting noise signals according to claim 16, wherein the first polarity pattern and the second polarity pattern sum to zero, and the first portion and the second portion of the predetermined time period are consecutive time slots in the predetermined time period.

18. The method of detecting noise signals according to claim 16, wherein the first polarity pattern and the second polarity pattern sum to zero, and the first portion and the second portion of the predetermined time period are consecutive groups of time slots in the predetermined time period.

19. The method of detecting noise signals according to claim 16, wherein the first polarity pattern subtracted by the second polarity pattern equals to zero, and the first portion and the second portion of the predetermined time period are consecutive groups of time slots in the predetermined time period.

20. The method of detecting noise signals according to claim 15, wherein the step of sensing the sense signals from the at least one sense line during the predetermined time period comprises integrating the sense signals over time in order to convert the sense signals to digital sense signals.

21. The method of detecting noise signals according to claim 15, wherein the step of deriving the magnitude of the noise signal according to the sense signals comprises summing the sense signals.
